(19) United States
(12) Patent Application Publication
(10) Pub. No.: US 2003/0033975 A1
(43) Pub. Date: Feb. 20, 2003

(54) Method of forming a planar waveguide core

(76) Inventor: Michael Bazylenko, Eveleigh (AU)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 09/931,981

(22) Filed: Aug. 17, 2001

(51) Int. Cl. C30B 23/00; C30B 25/00; C30B 28/12; C30B 28/14

(52) U.S. Cl. 117/84

(57) ABSTRACT

A method of depositing a waveguide core in a trench formed between opposed sidewalls of adjacent first and second cladding structures of a planar substrate. The method comprises the steps of depositing a waveguide material in the trench, preferentially etching the deposited waveguide material at or near upper regions of the opposed sidewalls, and controlling at least one parameter of the deposition process so as to form a waveguide core in the trench from the deposited waveguide material. The preferential etching step may be conducted in a manner which increases optical confinement in the deposited waveguide core in the trench, or in a manner which reduces shadowing effects in the trench.

### TECHNICAL FIELD

The present invention relates broadly to a method of forming a planar waveguide core, and in particular, a method of forming a waveguide core in a trench between adjacent first and second cladding structures of a planar substrate. The present invention also extends to optical components fabricated utilising the method, and to optical components assemblies incorporating a component fabricated utilising the method.

### BACKGROUND OF THE INVENTION

Planar optical waveguides can be formed in a number of different ways. One way involves depositing a core layer on a planar buffer layer and etching the core layer into a core structure having a channel waveguide geometry. The core structure is then coated in a layer of optical cladding material. Both the buffer layer and cladding layer have a lower refractive index than the core structure in order to optically isolate the core from the substrate and surrounding environment.

An alternative method of fabricating a planar optical waveguide involves depositing waveguide core material in a trench formed between adjacent cladding structures on a buffer layer which is in turn formed on a planar substrate. In such a waveguide structure, the buffer layer and adjacent cladding structures have a lower refractive index than the waveguide core material in order to optically isolate the waveguide core. Typically, a further low refractive index upper cladding layer is subsequently formed over the waveguide core deposited in the trench so as to completely encapsulate the waveguide core in lower refractive index material. In some circumstances, the core formed with this method can have smoother sidewalls than a core formed by etching back a core layer, as described above. The trench into which the waveguide core is to be deposited may be of a width comparable to or smaller than the sidewall heights of the adjacent first and second cladding structures defining the trench. When the waveguide core is formed by plasma-enhanced chemical vapour deposition (PECVD), material is typically deposited from a range of directions. If the heights of the sidewalls are comparable to the width of the trench defined therebetween, the cladding structures tend to cast shadows over the trench during the deposition process. As a result, the deposited waveguide material tends to be thickest around upper regions of the sidewalls. As the deposition process continues, the deposited waveguide material are gradually forms structures which extend from the upper regions of the sidewalls and overhang the trench, which in turn enhances the shadowing effect. Eventually, the overhanging regions join together, forming an air bubble in the trench which prevents the formation of a uniform waveguide core. Clearly, the presence of such an air bubble is undesirable in the formation of a waveguide core for optical light propagation.

In order to prevent the formation of such an air bubble, overhanging material in the trench may be removed by depositing the waveguide core in stages and periodically heating the waveguide, typically at temperatures above 1000° C., so as to cause the deposited material to reflow. However, there are many situations in which it is particularly undesirable to heat a waveguide structure to such high temperatures, such as when the waveguide is integrated with micro-electronic devices.

It is noted here that the shadowing effect described above is not limited to PECVD. Rather, the shadowing effect can be encountered in gas or vacuum-phase deposition technique, albeit to different degrees.

Another method of fabricating a planar optical waveguide involves depositing waveguide core material in a trench defined by adjacent first and second cladding structures and is characterised by a width that is larger than the sidewall heights of the adjacent cladding structures. In such a waveguide structure, shadowing effects during the waveguide core material deposition in the trench are reduced, and deposition can occur without formation of an air bubble in the trench. However, where deposition of waveguide core material occurs on the adjacent cladding structures as well as in the trench, optical confinement in the deposited waveguide core in the trench decreases as the amount of waveguide material deposited at or near upper regions of the opposed sidewalls increases. This is because of optical leakage through the waveguide core material at or near the upper regions out of the waveguide core in the trench. As a result, there exist constraints in the design of such waveguide structure fabricated in such a manner.

At least preferred embodiments of the present invention seek to provide an alternative method for depositing a waveguide core in a trench between adjacent cladding structures which addresses at least one of the problems identified above.

### SUMMARY OF THE INVENTION

In accordance with a first aspect of the present invention there is provided a method of depositing a waveguide core in a trench formed between opposed sidewalls of adjacent first and second cladding structures of a planar substrate, the method comprising the steps of depositing a waveguide material in the trench, preferentially etching the deposited waveguide material at or near upper regions of the opposed sidewalls, and controlling at least one parameter of the deposition process so as to form a waveguide core in the trench from the deposited waveguide material.

The preferential etching step may be conducted in a manner which increases optical confinement in the deposited waveguide core in the trench.

The preferential etching step may be conducted in a manner which reduces shadowing effects in the trench.

The parameter of the deposition process which is controlled may comprise one or more parameters in a group comprising substrate temperature, deposition rate, dopant material, annealing conditions, precursor flow rate, and total processing pressure during the deposition.

The method may further comprise, after the trench has been substantially filled, removing any excess waveguide material deposited on regions outside of the trench.

Preferably, the waveguide material is deposited and etched such that the resultant waveguide core in the trench is substantially free of macroscopic and microscopic voids.

The trench may be in the form of a trench formed in a planar cladding layer, the first and second cladding structures comprising respective portions of the cladding layer which define sidewalls of the trench.

Alternatively, the first and second cladding structures may be in the form of raised cladding structures formed on the planar substrate defining the trench therebetween.

The planar substrate may comprise an optical buffer layer formed on an underlying substrate wafer, for optically isolating the waveguide core from the substrate wafer. The buffer layer may comprise a silica-based layer and the substrate wafer may comprise a silicon wafer.

The waveguide core may comprise one or more of a silica-based material, a metaloxide-based material, a metal-nitride-based material, a metal-sulfide-based material, a chalcogenide-based material, or a titanate material of Perovskite structure such as PLZT. In particular, the waveguide core material may comprise an aluminium-oxide-based material. For example, the waveguide core material may comprise aluminium oxide doped with erbium and/or ytterbium. Such an embodiment has applications as an optical amplifier.

The upper regions of the sidewalls may have a rounded profile.

The step of etching is preferably conducted in a manner which reduces shadowing effects resulting from an accumulation of deposited waveguide material at or near upper regions of the opposed sidewalls. Advantageously, the step of etching is conducted in a manner which reduces shadowing effects by removing overhanging structures extending from upper regions of the opposed sidewalls, the overhanging structures resulting from a build-up of waveguide material.

The step of etching may comprise ion bombarding the deposited waveguide material so as to cause sputtering. The ions involved in the ion bombardment may comprise argon (Ar) ions and are preferably directed at an angle of substantially 90° to the substrate.

The step of etching may be conducted simultaneously with the step of depositing the waveguide material. Alternatively, the step of etching and the step of depositing the waveguide material may be conducted sequentially.

The step of etching may be conducted so as to control the energy of waveguide material which is etched away but subsequently re-deposited in the trench, whereby a material property of the waveguide material deposited in the trench is controlled.

The step of depositing the waveguide material preferably comprises PECVD. The PECVD may be conducted in the absence of nitrogen or nitrogen-containing gases.

The PECVD process may be conducted such that the etching results from ion bombardment arising from the PECVD process. The ion bombardment arising from the PECVD may be controlled by controlling one or more deposition parameters in a group comprising: power input into the PECVD; frequency of a radio frequency (RF) power supply for the PECVD; power of one power supply in a dual-frequency power supply for the PECVD; substrate temperature; and argon-to-precursor vapour ratio during the PECVD.

The PECVD process may comprise utilising a liquid source for the precursor vapour.

The method may further comprise a step of annealing the deposited waveguide material to trim a material property of the waveguide core. The material property may comprise one or more of a group comprising refractive index, birefringence, and density of the waveguide core.

The method may further comprise a step of doping the waveguide core with a refractive-index-modifying dopant during or after the deposition of the waveguide material.

The step of depositing the waveguide material may comprise depositing a plurality of layers of the waveguide material, wherein at least one of the layers exhibits a compressive stress and the remaining layer(s) exhibits a tensile stress which at least partially compensates for the compressive stress. Preferably, the completed waveguide core has substantially zero net stress.

Where the etching is a result of ion bombardment during the PECVD, the waveguide core may be formed with a predetermined stress by controlling the etching component during the deposition of the waveguide material.

The etching may be conducted in a manner which prevents etching of the adjacent first and second cladding structures.

Alternatively, the etching may further comprise etching the adjacent first and second cladding structures at upper regions of the opposed sidewalls.

Where the etching and deposition occur sequentially, the steps of depositing and etching the waveguide material may be conducted in respective dedicated processing chambers.

Where the etching is conducted in a manner which reduces shadowing effects in the trench, an aspect ratio (ratio of depth to width) of the trench may be at least 0.5:1. In one embodiment, the aspect ratio is at least 0.8:1.

The method may further comprise depositing a cladding layer over the waveguide core and the adjacent first and second cladding structures.

In accordance with a second aspect of the present invention there is provided a method of depositing a waveguide core in a trench formed between opposed sidewalls of adjacent first and second cladding structures of a planar substrate, the method comprising the steps of modifying the first and second cladding structures so as to modify a cross-sectional profile of the trench, depositing a waveguide material in the modified trench, and controlling at least one parameter of the deposition process so as to form a waveguide core from the deposited waveguide material, wherein the cross-sectional profile of the trench is modified such that there is a reduction in shadowing effects in the trench between the adjacent first and second cladding structures.

The parameter of the deposition process may comprise one or more parameter in a group comprising substrate temperature, deposition rate, dopant material, annealing conditions, precursor flow rate, and total processing pressure during the deposition.

The method may further comprise, after the trench has been substantially filled, removing any excess waveguide material deposited on regions outside the trench.

Preferably, the first and second cladding structures are modified such that the resultant waveguide core is substantially free of macroscopic and microscopic voids.

The trench may be in the form of a trench formed in a planar cladding layer, the first and second cladding structures comprising respective portions of the cladding layer which define sidewalls of the trench.

Alternatively, the first and second cladding structures may be in the form of raised cladding structures formed on the planar substrate defining the trench therebetween.

The planar substrate may comprise an optical buffer layer formed on an underlying substrate wafer, for optically isolating the waveguide core from the substrate wafer. The buffer layer may comprise a silica-based layer and the substrate wafer may comprise a silicon wafer.

The waveguide core may be formed from any one of the waveguide materials described above in the first aspect of the invention.

The first and second cladding structures may be modified such that at least portions of the opposed sidewalls are sloped with respect to the substrate.

The step of modifying the first and second cladding structures may comprise etching the first and second cladding structures such that upper regions of the sidewalls are etched preferentially.

The sputtering may be a result of ion bombardment, such as with Ar ions. Preferably the ions involved in the ion bombardment are directed at an angle of substantially 90° to the substrate.

An aspect ratio (ratio of depth to width) of the trench may be at least 0.5:1. In one embodiment, the aspect ratio is at least 0.8:1.

The method may further comprise depositing a cladding layer over the waveguide core and the first and second cladding structures.

In accordance with a third aspect of the present invention there is provided an optical component fabricated utilising the methods described in either the first or second aspect of the invention.

In accordance with a fourth aspect of the present invention there is provided an optical component assembly incorporating a component fabricated utilising the methods described in either the first or second aspect of the invention.

### BRIEF DESCRIPTION OF THE DRAWINGS

Embodiments of the present invention will now be described, by way of example only, with reference to the accompanying drawings.

FIGS. 1A to F are schematic drawings illustrating an embodiment of a method of depositing a waveguide core in a trench between adjacent cladding structures.

FIG. 2 is a schematic drawing of a fabrication system for implementing a method embodying the present invention.

FIG. 3 is a schematic drawing showing another fabrication system for implementing a method embodying the present invention.

FIGS. 4A to F are schematic diagrams illustrating another embodiment of a method of forming a waveguide core in a trench between adjacent cladding structures.

FIGS. 5A to F are schematic drawings illustrating another embodiment of a method of forming a waveguide core in a trench between adjacent cladding structures.

FIGS. 6A to C are schematic drawings illustrating another embodiment of a method of forming a waveguide core in a trench between adjacent cladding structures.

### DETAILED DESCRIPTION OF THE EMBODIMENTS

The embodiments described below provide a method of depositing a waveguide core in a trench between adjacent waveguide structures in which the formation of an air bubble in the deposited waveguide core is prevented.

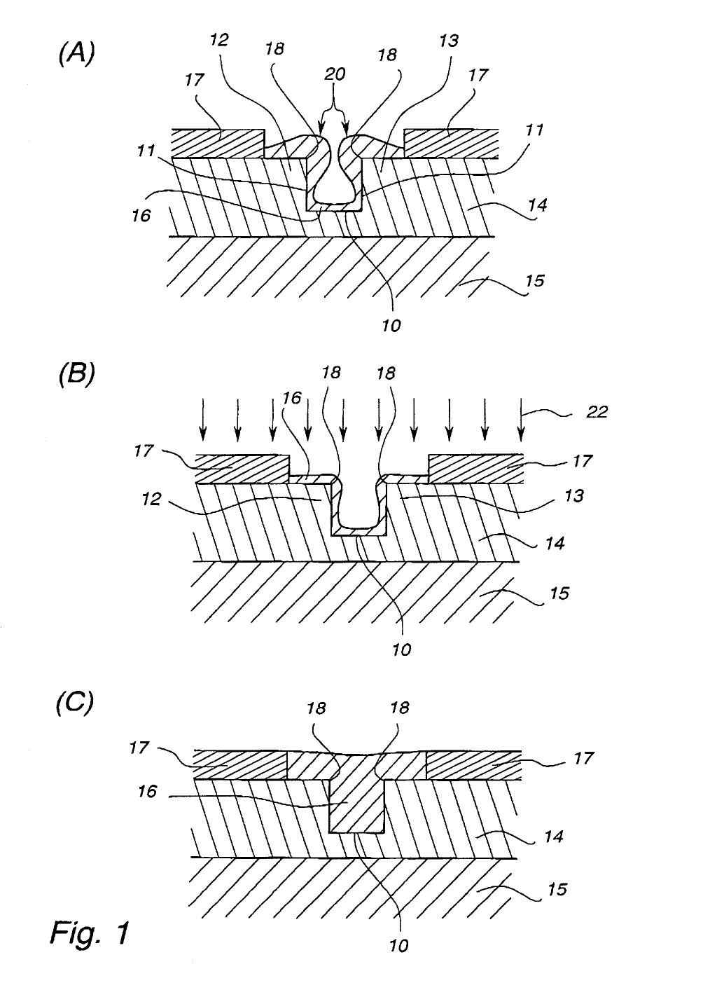

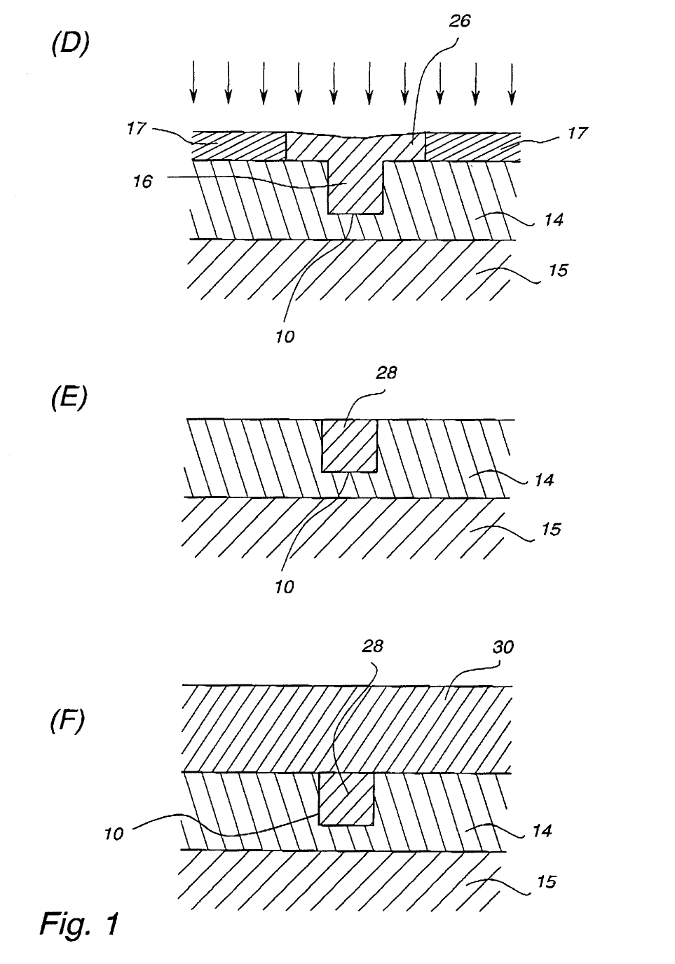

The principles of a method embodying the present invention will initially be described with reference to FIGS. 1A to F. FIG. 1A shows a trench 10 formed between sidewalls 11 of first and second cladding structures 12,13. In this embodiment, first and second cladding structures 12,13 are part of a larger silica optical buffer layer 14 which separates the trench 10 from an underlying substrate wafer in the form of silicon wafer 15. The trench 10 in the example embodiment was formed by etching the buffer layer 14 through an appropriate mask. However, it will be appreciated that the trench 10 in alternative embodiments can be formed through any other suitable technique. In FIG. 1A, silica-based waveguide material 16 has been deposited in the trench 10 so as to partially fill the trench. A mask 17 has been used to minimise excess deposition of waveguide material. It can be seen in FIG. 1A that the width of the trench 10 is comparable to the depth of the trench i.e. the aspect ratio of the trench is approximately 1:1. Thus, the corner portions 18 of the buffer layer 14 tend to cast a shadow which gives rise to a deposition rate in the trench which increases with height above the bottom of the trench 10. The deposition rate is therefore lowest near the bottom of the trench 10 and highest at the corner portions 18 of the buffer layer 14. The non-uniform deposition rate in the trench 10 results in the formation of overhanging waveguide material 20 at or near the corner portions 18.

The overhangs 20 eventually enhance the shadowing effect between the corner portions 18 and can eventually result in the formation of an air bubble as described in the background section. However, in the method embodying the present invention (illustrated in FIG. 1B) a sputtering step is conducted to remove overhangs 20. In the sputtering step, the waveguide material 16 is bombarded with argon ions at an angle of 90° to the wafer 15, as indicated by arrows 22. Although the entire upper surface of the waveguide material 16 is exposed to the ion bombardment, the waveguide material deposited at or near the corner portions 18 is sputtered away at a higher rate than waveguide material deposited on other surfaces. As a result, the overhangs 20 are preferentially etched. The reason waveguide material is etched preferentially at or near the corner portions 18 is based on the inventor's realisation that the sputter rate from ion bombardment is at a maximum when ions impact a surface at an angle which is smaller than 90° and greater than 0°, and typically around 60°. Thus, surfaces perpendicular or parallel to the bombarding ions are sputtered a lower rate than surfaces which are angled towards the ions, such as at or near the corner portions 18.

The removal of overhangs 20 reducing the shadowing effect in the trench 10 during subsequent depositions of waveguide material 16 and allows the trench to be filled without including air bubbles, as shown in FIG. 1C. The deposition and etching steps can be repeated as often as necessary in order to fill the trench without including air bubbles.

After the trench 10 has been filled with waveguide material, the entire substrate structure is subjected to a further bombardment with argon ions, as indicated by arrows 24 in FIG. 1D. The purpose of this further sputtering step is to remove excess waveguide material 26 from regions outside the trench 10. As a result, substantially all the excess waveguide material 26 is eventually removed and the buffer layer 14 and completed waveguide core 28 are exposed as shown in FIG. 1E.

In a final processing step, shown in FIG. 1F, a silica cladding layer 30 is deposited over the buffer layer 14 and the waveguide core 28 in order to encapsulate the core in a lower refractive index material.

In the method described above, the deposition of waveguide material and etching occur simultaneously. However, it will be appreciated by a person skilled in the art that the principles described above with reference to FIGS. 1A-F are equally applicable to methods in which the deposition and etching occur during one processing step.

Furthermore, it is noted that during the removal overhangs 20 shown in FIG. 1B, a portion of the waveguide material sputtered away during to ion bombardment is re-deposited in the trench 10. The energy of the re-deposited particles can be controlled through appropriate control of the ion bombardment energy. The resultant properties of the waveguide material in the trench 10 can thus be controlled. Accordingly, waveguide material properties in the lower regions of the trench, such as refractive index and density, can be adjusted to achieve a desirable effect.

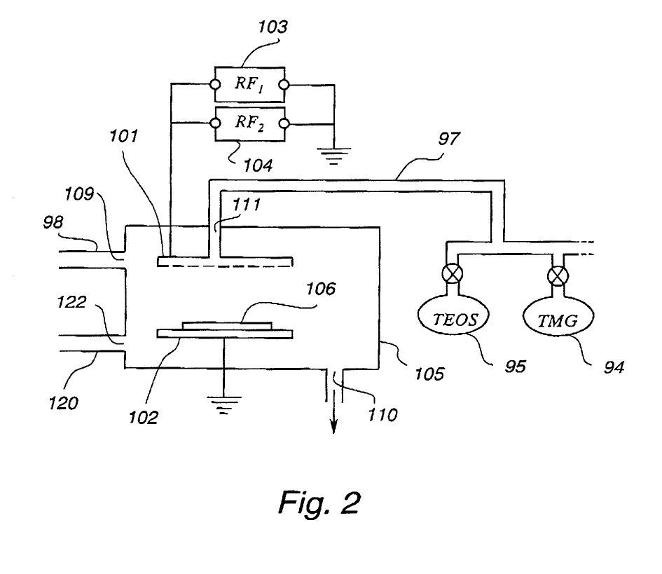

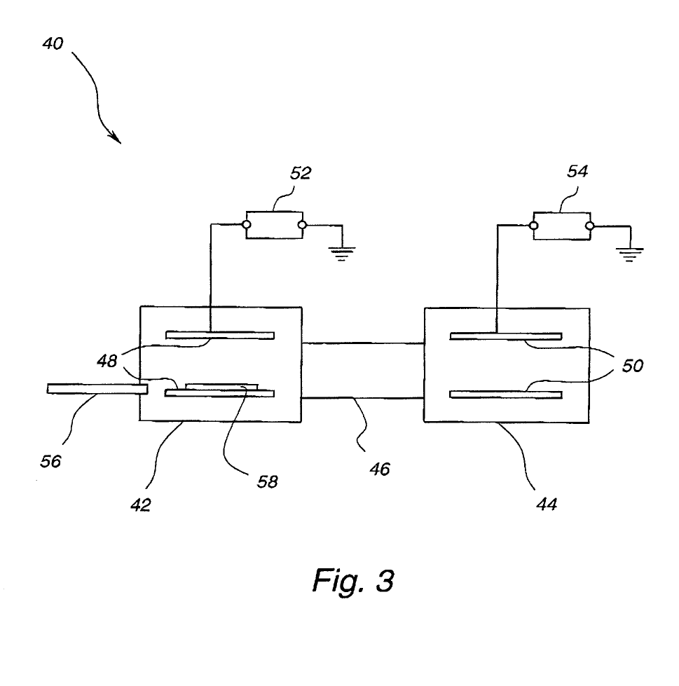

Two alternative fabrication systems for depositing waveguide material will now be described with reference to FIGS. 2 and 3.

Turning initially to FIG. 2, a PECVD chamber 105 comprises two opposing electrodes 101, 102, which form a circuit with a series of RF power supplies 103, 104. As in conventional PECVD chambers, an RF plasma discharge is generated between the two electrodes 101, 102 in the presence of a precursor vapour during the deposition of waveguide core material.

A pump port 110 leading to a vacuum pump (not shown) is provided for evacuating the PECVD chamber 105. A substrate 106 is supported on the bottom electrode 102, and includes a silica optical buffer layer in which the trench is formed (as shown in FIG. 1A).

Oxygen is delivered in a gas-feed pipe 98 and introduced into the PECVD chamber 105 through port 109 in a sidewall of the PECVD chamber 105. Another gas-feed pipe 120 and through port 122 are provided for the introduction of argon into the PECVD chamber 105. A further port 111 is utilised to introduce a precursor vapour from a precursor-feed pipe 97 connected to a vessel 95, which in the example embodiment contains liquid tetraethoxysilane (TEOS) for the formation of a silica-based waveguide core.

It will be appreciated by the person skilled in art that provisions for valves are made in the feed pipes 97, 98 and 120 but those are not illustrated for simplicity.

In the example embodiment, a further vessel 94 is connected to the precursor-feed pipe 97, the vessel 94 containing tetramethylgermanium (TMG). TMG can be utilised as a dopant precursor during the deposition of silica-based waveguide core material from the TEOS liquid source for controlling optical properties in the resultant waveguide core.

It will be understood that precursors other than TEOS and/or dopant precursors other than TMG can be used to form a waveguide core.

Of the two RF power supplies 103, 104, a first RF power supply 103 operates at a frequency of 13.56 MHz, and a second RF power supply 104 operates at a lower frequency of 450 kHz.

A substrate heating apparatus (not shown) is provided for heating the substrate 106 during the deposition to temperatures of the order of 350° C. in order to deposit a silica-based waveguide core from the TEOS and TMG precursors. The substrate heating apparatus is not shown here for simplicity. Also, the person skilled in the art will understand that the RF circuitry is shown in FIG. 2 in a simplified form. For example, an impedance matching circuit would normally be used with each power supply 103, 104 but is not illustrated here for simplicity. Any one of a number of commercially-available RF power supplies may be used in the present invention. The RF power supplies 103, 104 can be connected in a number of different ways without departing from the spirit or scope of the present invention.

During the PECVD deposition of waveguide core material, simultaneous ion bombardment of the deposited core material can be enhanced by introducing argon or other inert gas into the PECVD chamber 105 through port 122. Due to the geometry of the electrodes 101, 102, the argon ions impact on growing cladding layer at an angle of substantially 90°. The flux and energy of ion bombardment is selected to be sufficient to preferentially sputter surfaces which are sloped relative to the direction of ion bombardment (as shown in FIG. 1B).

The degree of ion bombardment can be controlled by adjusting one or more of the following deposition parameters:

(a) The power input into the PECVD;

(b) The frequency of the 450 kHz RF power supply for the PECVD;

(c) The power of the 450 kHz power supply;

(d) The substrate temperature;

(e) The argon-to-precursor vapour flow ratio during the PECVD.

Furthermore, at least one deposition parameter is controlled such that the deposited material is capable of functioning as an optical waveguide core, i.e. possess suitable thickness, refractive index-profile, optical transparency etc. The at least one parameter can include any one of the above listed parameters and others, such as concentration and type of dopant. The deposition parameters are preferably controlled so as to produce a waveguide core which has zero net stress. The stress in films deposited by PECVD may be made more tensile (less compressive) by increasing the deposition rate. Also, the film stress may be made more tensile stress by decreasing the average ion bombardment energy during the deposition. Thus, in general, the stress in a waveguide core can be made more tensile by increasing the ratio of deposition rate to average ion bombardment energy. Information about controlling cladding layer stress during PECVD are disclosed in pending U.S. provisional patent application No. 60/290,374 entitled “Silica-based optical device fabrication” filed in the name of Michael Bazylenko (assigned to Redfern Integrated Optics Pty Ltd), the disclosure of which is hereby specifically incorporated by cross-reference.

Turning now to FIG. 3, another fabrication system 40 embodying the present invention comprises a dedicated deposition chamber 42 and a dedicated sputtering chamber 44 connected via a transfer chamber 46.

It will be appreciated by the person skilled in the art that the deposition chamber 42, the sputtering chamber 44 and the transfer chamber 46 are provided with suitable evacuation means known in the art to effect vacuum transfer between different vacuum chambers. Those evacuation means have been omitted from FIG. 3 for simplicity.

The deposition chamber 42 and the sputtering chamber 44 comprise pairs of electrodes 48, 50 respectively, which are connected to RF power supplies 52, 54 respectively. Again, an RF plasma discharge is generated between the respective pairs of electrodes 48, 50 to either deposit the waveguide core in the presence of a waveguide material precursor (deposition chamber 42) or to sputter in an argon/oxygen atmosphere (sputtering chamber 44).

A transfer robot arm 56 is provided for effecting transfer of a wafer substrate 58 between the deposition chamber 42 and the sputtering chamber 44. Again, it will be appreciated that suitable evacuation means are provided in conjunction with the transfer rod such as a differential pumping system, but those have been omitted for simplicity.

When utilising a fabrication system of the type shown in FIG. 3 with dedicated and separate deposition and sputtering chambers 42, 44, it may be preferable to reduce the number of sequential deposition and sputtering steps in order to reduce the number of times the substrate 58 is transferred between chambers 42,44, thereby increasing the efficiency of the overall deposition process.

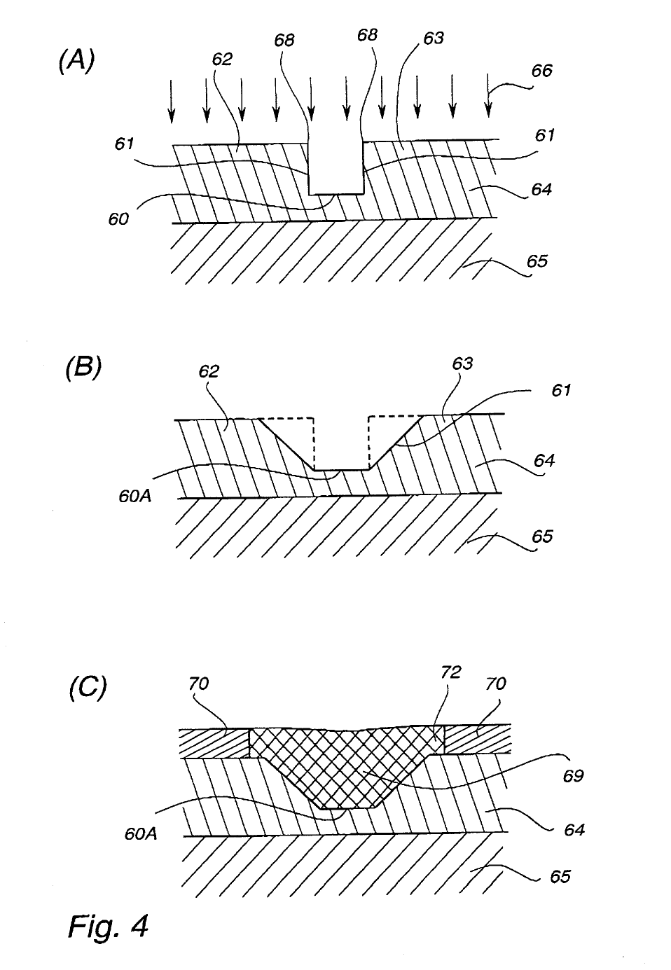

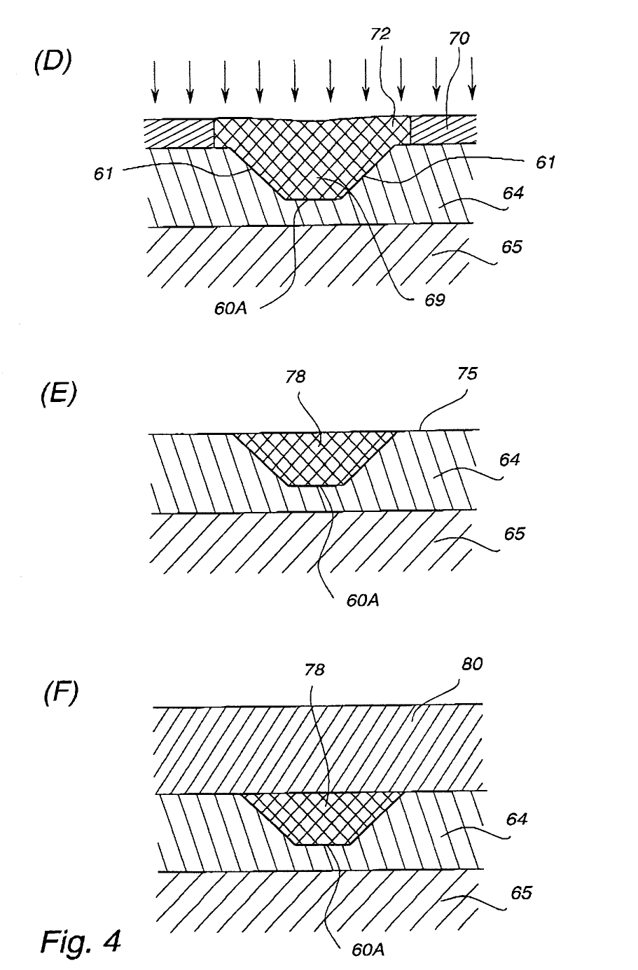

In FIGS. 4A-F, the principles of an alternative method of depositing a waveguide core in a trench between two closely-adjacent cladding structures will now be described. In a first step, shown in FIG. 4A, a substrate structure comprising a trench 60 formed between sidewalls 61 of first and second cladding structures 62, 63. Again, the first and second cladding structures 62, 63 are part of a larger silica optical buffer layer 64 which separates the trench 60 from an underlying silicon wafer 65. The trench 60 is formed by etching buffer layer 64 through a mask (not shown). Since the aspect ratio of the trench 60 is approximately 1:1, there is a tendency for air bubbles to be incorporated when the trench is filled with waveguide material. This problem is addressed in this embodiment by modifying the cross-sectional profile of the trench 60 prior to filling the trench with waveguide material. The cross-sectional profile of the trench 60 is modified by bombarding the entire buffer layer 64 with argon ions, indicated by arrows 66, at 90° to the substrate.

The flux and energy of the sputtering is controlled so as to preferentially remove material from corner portions 68. As material is gradually removed from the corner portions 68, regions of the sidewalls gradually become sloped with respect to the wafer 64. In the example embodiment, the sputtering step has been continued until the entire height of each sidewall is sloped relative to the wafer 64, as shown in FIG. 4B. The original cross-sectional profile of the trench 60 prior to etching is shown in dashed lines.

The inventor has found that shadowing effects during the deposition of a waveguide core in the modified trench 60A shown in FIG. 4B are substantially eliminated, thus enabling waveguide material 69 to be continuously deposited without forming any air bubbles in the trench 60A, as shown in FIG. 4C. As further shown in FIG. 4C, a mask 70 is utilised to reduce deposition of silica-based waveguide material outside the modified trench 60A.

As shown in FIG. 4D, the excess waveguide material 72 is subsequently removed through an etching step, which in this case comprises ion milling. The etching is continued until substantially all the excess waveguide material 72 is removed and the top surface 75 of the buffer layer 64 is exposed, as shown in FIG. 4E. This leaves the trench 60A completely filled, forming a waveguide core 78.

In a final step, shown in FIG. 4F, a silica cladding layer 80 is deposited over the waveguide core 78 and buffer layer 64 to encapsulate the waveguide core 78 in lower refractive index material and therefore optically isolate the waveguide core 78.

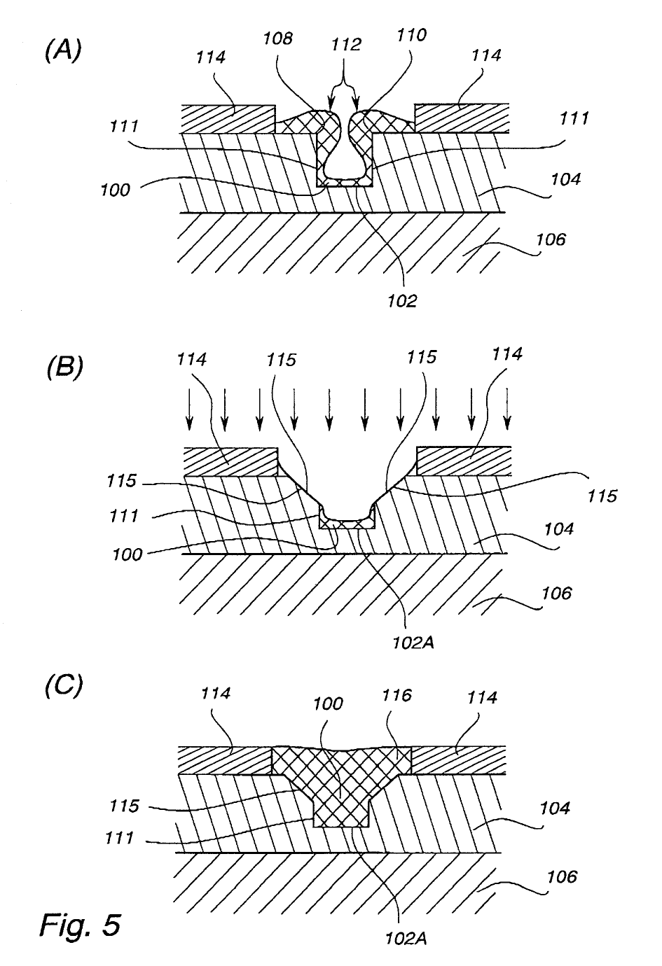

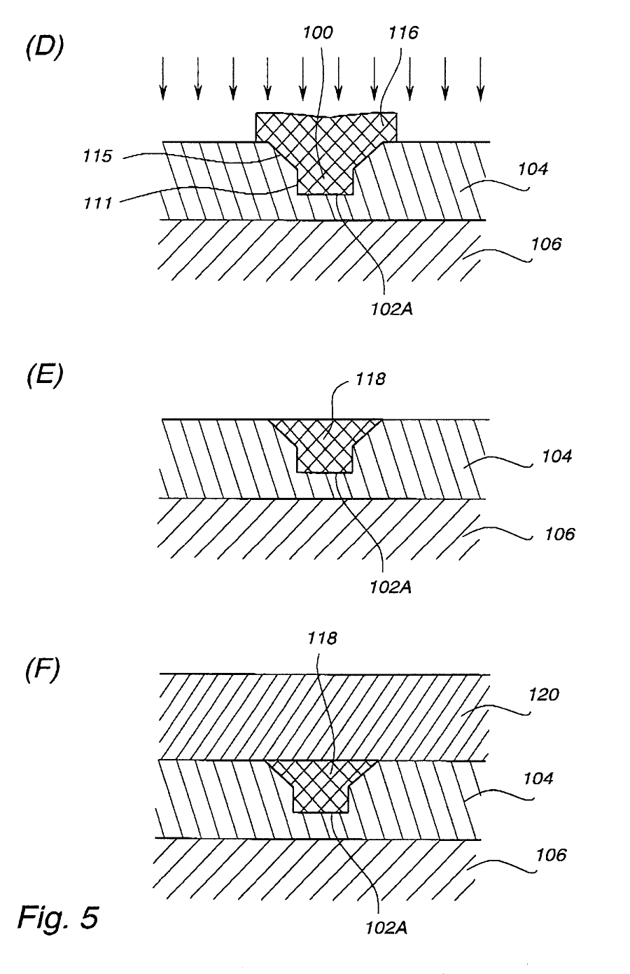

Referring to FIGS. 5A-F, the principle of a further alternative method of depositing a waveguide core in a high-aspect-ratio trench defined by closely-adjacent cladding structures will now be described. In a first step, shown in FIG. 5A, a layer of silica-based waveguide material 100 is deposited over and in a trench 102 formed in a silica buffer layer 104, which is in turn formed on a silicon wafer 106. A mask 114 is used to minimise deposition of excess waveguide material. Again, a higher deposition rate is encountered around upper corners 108, 110 of the sidewalls 111 defining the trench 102, which results in the formation of overhanging waveguide material 112 on upper regions of the sidewalls. In a second step shown in FIG. 5B ion bombardment at an angle of 90° to the wafer 106 using argon ions is conducted in a similar manner to the embodiment described above with reference to FIGS. 1A-F. However, in this embodiment the sputtering step is continued after the overhangs 112 are removed (FIG. 5B), so as to remove the corners 108, 110. As a result, the cross-sectional profile of the trench is changed such that upper regions 115 of the sidewalls are partially sloped relative to the wafer 106.

Referring to FIG. 5C, the inventor has found that shadowing effects in the modified trench 102A are substantially eliminated during a subsequent deposition of further waveguide material. Thus, the trench 102A can be filled with waveguide material 100 without forming an air bubble, as shown in FIG. 5C. The inventor has further found that this method of depositing part of the waveguide core, followed by partially etching back into the sidewalls of the trench and subsequently depositing more of the waveguide material 100 into the modified trench 102A provides a process suitable for high throughput while reducing the degree to which the trench structure is modified. The deposition is again conducted utilising the mask 114 to minimise deposition of excess waveguide material 116 outside the modified trench 102A.

In a subsequent step, shown in FIG. 5D, the excess waveguide material 116 is etched away until top surfaces of the buffer layer 104 are exposed. This leaves the modified trench 102A completely filled, forming a waveguide core 118, as shown in FIG. 5E.

In a final step shown in FIG. 5F, a silica cladding layer 120 is deposited over the waveguide core 118 and the buffer layer 104 to encapsulate the waveguide core 118 in lower refractive index material so as to optically isolate the waveguide core 118.

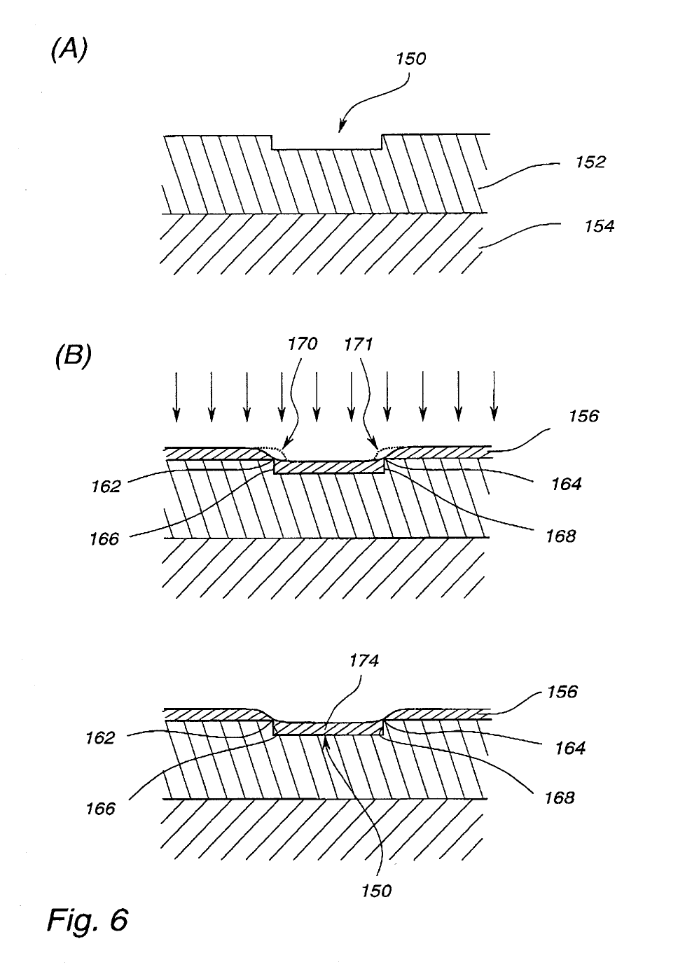

In a method of fabricating a waveguide core in a low-aspect-ratio trench embodying the present invention shown in FIGS. 6A to C, a trench 150 is formed in a buffer layer 152. The buffer layer 152 in turn is formed on a silicon wafer 154 (FIG. 6A).

During deposition of a silica-based waveguide core material 156 (FIG. 6B), preferential sputtering is conducted through ion bombardment at an angle of 90° to the wafer 154 using argon ions. As a result, waveguide core material deposited at or near upper regions 162, 164 of opposing sidewalls 166, 168 respectively is removed preferentially, i.e. the amount of deposited waveguide core material at or near the upper regions 162, 164 is reduced. In FIG. 6B, dotted lines 170, 172 outline the profile of deposited waveguide material that would be created without sputtering to illustrate the preferential removal of waveguide material at or near the upper regions 162, 164.

As shown in FIG. 6C, a waveguide core 174 can thus be fabricated in the trench 150 with an increased optical confinement, as a result of reduced leakage through waveguide material at or near the upper regions 162, 164.

It will be appreciated by the person skilled in the art that numerous modification and/or variations may be made to the present invention as shown in the specific embodiments without departing from the spirit or scope of the invention as broadly described. The present embodiments are, therefore, to be considered in all respects to be illustrative and not restrictive.

In the claims that follow and in the summary of the invention, except where the context requires otherwise due to express language or necessary implication the word “comprising” is used in the sense of “including”, i.e. the features specified may be associated with further features in various embodiments of the invention

We claim:

1. A method of depositing a waveguide core in a trench formed between opposed sidewalls of adjacent first and second cladding structures of a planar substrate, the method comprising the steps of:
depositing a waveguide material in the trench,
preferentially etching the deposited waveguide material at or near upper regions of the opposed sidewalls, and
controlling at least one parameter of the deposition process so as to form a waveguide core in the trench from the deposited waveguide material.

2. A method as claimed in claim 1, wherein the preferential etching step is conducted in a manner which increases optical confinement in the deposited waveguide core in the trench.

3. A method as claimed in claim 1, wherein the preferential etching step is conducted in a manner which reduces shadowing effects in the trench.

4. A method as claimed in claim 3, wherein the method further comprises, after the trench has been substantially filled, removing any excess waveguide material deposited on regions outside of the trench.

5. A method as claimed in claim 3, wherein the waveguide material is deposited and etched such that the resultant waveguide core in the trench is substantially free of macroscopic and microscopic voids.

6. A method as claimed in claim 1, wherein the planar substrate comprises an optical buffer layer formed on an underlying substrate wafer, for optically isolating the waveguide core from the substrate wafer.

7. A method as claimed in claim 1, wherein the waveguide core comprises one or more of a silica-based material, a metal-oxide-based material, a metal-nitride-based material, a metal-sulfide-based material, a chalcogenide-based material, or a titanate material of Perovskite structure.

8. A method as claimed in claim 7, wherein the waveguide core material comprises an aluminium-oxide-based material.

9. A method as claimed in claim 7, wherein the waveguide core material comprises aluminium oxide doped with erbium and/or ytterbium.

10. A method as claimed in claim 1, wherein the step of etching comprises ion bombarding the deposited waveguide material so as to cause sputtering.

11. A method as claimed in claim 10, wherein the ions involved in the ion bombardment are directed at an angle of substantially 90° to the substrate.

12. A method as claimed in claim 1, wherein the stop of etching is conducted simultaneously with the step of depositing the waveguide material.

13. A method as claimed in claim 1, wherein the stop of etching and the step of depositing the waveguide material are conducted sequentially.

14. A method as claimed in claim 1, wherein the step of etching is conducted so as to control the thermal energy of waveguide material which is etched away but subsequently re-deposited in the trench, whereby a material property of the waveguide material deposited in the trench is controlled.

15. A method as claimed in claim 1, wherein the step of depositing the waveguide material comprises carrying out PECVD.

16. A method as claimed in claim 15, wherein the PECVD is conducted in the absence of nitrogen or nitrogen-containing gases.

17. A method as claimed in claim 16, wherein the PECVD process is conducted such that the etching as a result of ion bombardment arising from the PECVD process.

18. A method as claimed in claim 15, wherein the PECVD process comprises utilising a liquid source for the precursor vapour.

19. A method as claimed in claim 1, wherein the method further comprises a step of annealing the deposited waveguide material to trim a physical material property of the waveguide core.

20. A method as claimed in claim 1, wherein the step of depositing the waveguide material comprises depositing a plurality of layers of the waveguide material, wherein at least one of the layers exhibits a compressive stress and the remaining layer(s) exhibits a tensile stress which at least partially compensates for the compressive stress.

21. A method as claimed in claim 20, wherein the completed waveguide core has substantially zero net stress.

22. A method as claimed in claim 15, wherein, where the etching is a result of ion bombardment during the PECVD, the waveguide core is formed with a predetermined stress by controlling the etching component during the deposition of the waveguide material.

23. A method as claimed in claim 1, wherein the etching is conducted in a manner which prevents etching of the adjacent first and second cladding structures.

24. A method as claimed in claim 1, wherein the etching further comprises etching the adjacent first and second cladding structures at the upper regions of the opposed sidewalls.

25. A method as claimed in claim 1, wherein, where the etching and deposition occur sequentially, the steps of depositing and etching the waveguide material are conducted in respective dedicated processing chambers.

26. A method as claimed in claim 1, wherein the method further comprises depositing a cladding layer over the waveguide core and the adjacent first and second cladding structures.
